(19) United States
(12) Patent Application Publication
(10) Pub. No.: US 2025/0349498 A1
(43) Pub. Date: Nov. 13, 2025

(54) SPLIT-COLUMN ACCELERATION TUBE FOR SCANNING ELECTRON MICROSCOPE

(71) Applicant: FEI COMPANY, Hillsboro, OR (US)

(72) Inventors: Jan Stopka, Brno (CZ); Bohuslav Seda, Blansk (CZ)

(21) Appl. No.: 18/660,569

(22) Filed: May 10, 2024

(51) Int. Cl. H01J 37/15; H01J 37/05; H01J 37/145; H01J 37/147

(52) U.S. Cl. CPC H01J 37/15; H01J 37/05; H01J 37/145; H01J 37/1471

(57) ABSTRACT

Embodiments of the present disclosure include systems, methods, algorithms, and non-transitory media storing computer-readable instructions for charged particle imaging and microanalysis. A charged particle beam system can include an objective lens assembly, defining an aperture collocated with a first axis. The system can include a bifurcated acceleration tube. The acceleration tube can include a primary segment, a secondary segment, intersecting the primary segment, the secondary segment being oriented at an angle, a, relative to the first axis, and a common segment, disposed at least partially in the aperture. The system can include a separator. The separator can include one or more charged-particle optical elements disposed in the common segment and configured to apply a deflection force to electrons having a negative velocity in a first direction. The deflection force can redirect the electrons toward a second direction substantially aligned with a second axis.

### TECHNICAL FIELD

Embodiments of the present disclosure are directed to charged particle microscope systems, as well as algorithms and methods for their operation. In particular, some embodiments are directed toward techniques for secondary electron microscopy and microanalysis in multibeam systems.

### BACKGROUND

Charged particle microscopy is a well-known and increasingly important technique for imaging microscopic objects, particularly in the form of electron microscopy. The basic genus of the electron microscope finds practical application in the form of a variety of apparatus species, such as the Transmission Electron Microscope (TEM), Scanning Electron Microscope (SEM), and Scanning Transmission Electron Microscope (STEM), and also into various sub-species.

In an SEM, irradiation of a specimen by a scanning electron beam precipitates emanation of “auxiliary” radiation from the specimen in the form of secondary electrons, backscattered electrons, X-rays, and cathodoluminescence (infrared, visible and/or ultraviolet photons), for example. One or more components of this emanating radiation is/are then detected and used for image accumulation purposes.

As an alternative to the use of electrons as irradiating beam, charged particle microscopy can also be performed using other species of charged particle. In this respect, the phrase “charged particle” may be understood as encompassing electrons, positive ions (e.g., Ga or He ions), negative ions, protons, and positrons, for example. In addition to imaging and performing (localized) surface modification (e.g., milling, etching, deposition, etc.), a charged particle microscope also may have other functionalities, such as performing spectroscopy, examining diffractograms, etc.

In all cases, a charged particle microscope (CPM) generally will comprise at least a radiation source (e.g., an electron source or ion gun), a beam directing system, a specimen holder, and a detector.

The detector can take many different forms depending on the radiation being detected. Examples include photodiodes, CMOS detectors, CCD detectors, photovoltaic cells, X-ray detectors (such as Silicon Drift Detectors and Si(Li) detectors), etc. In general, a CPM may comprise several different types of detector, selections of which can be invoked in different situations.

### SUMMARY

The terms and expressions which have been employed are used as terms of description and not of limitation, and there is no intention in the use of such terms and expressions of excluding any equivalents of the features shown and described or portions thereof, but it is recognized that various modifications are possible within the scope of the claimed subject matter. Thus, it should be understood that although the present claimed subject matter has been specifically disclosed by embodiments and optional features, modification and variation of the concepts herein disclosed can be resorted to by those skilled in the art, and that such modifications and variations are considered to be within the scope of this disclosure as defined by the appended claims. For example, the preceding aspects and various embodiments can be combined with one or more other aspects and/or embodiments of the same or other aspects.

In a first aspect, a charged particle beam system is described in reference to FIGS. 1-7B. The system can include an objective lens assembly, defining an aperture collocated with a first axis. The system can include an acceleration tube, defining a bifurcation. The acceleration tube can include a primary segment, substantially concentric with the first axis, a secondary segment, intersecting the primary segment at the bifurcation, the secondary segment being oriented and substantially concentric with a second beam axis at an angle, a, relative to the first axis, and a common segment, disposed at least partially in the aperture. The system can include a separator. The separator can include one or more charged-particle optical elements disposed in the common segment and configured to apply a deflection force to electrons having a negative velocity in a first direction. The deflection force can redirect the electrons toward a second direction substantially aligned with a second axis.

In some embodiments, the acceleration tube is configured to increase a magnitude of the negative velocity of the electrons in the first direction. The one or more charged-particle optical elements can include a Wien filter. The Wien filter can be coupled with control circuitry. The control circuitry can configure the Wien filter to apply negligible or substantially no deflection force to primary electrons having a positive velocity in the first direction. The separator can be coupled with bias circuitry configured to apply a bias potential to the separator.

In some embodiments, the system includes a projection system. The projection system can be disposed along the second axis. The projection system can include one or more electromagnetic elements disposed in the acceleration tube and coupled with bias circuitry configured to apply a potential to the electromagnetic elements. The projection system can include one or more electromagnetic elements disposed external to the acceleration tube. The projection system can include a stigmator assembly.

In some embodiments, the electrons are secondary electrons. The system can include an aperture array element, disposed on the first beam axis and configured to generate multiple beamlets of primary electrons having a nonzero velocity along the first beam axis in the first direction. The angle, a, can be a first angle. The one or more charged-particle optical elements can include a magnetic prism configured to redirect the electrons from the first direction to the second direction and to redirect primary electrons from a third direction to the first direction, the third direction being oriented at a second angle, B, relative to the first direction.

In some embodiments, the objective lens assembly includes a multiple-gap objective lens. The objective lens assembly can include a magnetic lens and an immersion lens or the magnetic lens and an electrostatic lens. The angle, a, can be from about 5 degrees to about 40 degrees.

In a second aspect, described in reference to FIG. 1 and FIG. 3-7B, an acceleration tube includes a primary segment, substantially concentric with a first axis, a secondary segment, contiguous with the primary segment at a bifurcation of the acceleration tube, the secondary segment being oriented and substantially concentric with a second axis at an angle, a, relative to the first axis, and a common segment. The acceleration tube can include a separator. The separator can include one or more charged-particle optical elements disposed in the common segment and configured to apply a deflection force to charged particles having a negative velocity in a first direction. The deflection force can redirect the electrons toward a second direction substantially aligned with a second axis.

In some embodiments, the acceleration tube can be configured to increase a magnitude of the negative velocity of the charged particles in the first direction. The one or more charged-particle optical elements can include a Wien filter. The Wien filter can be coupled with control circuitry configuring the Wien filter to apply negligible or substantially no deflection force to primary charged particles having a positive velocity in the first direction.

The acceleration tube can include a dielectric material serving as a physical tube, within which optical components are biased to a tube potential and external to which the optical components are coupled with ground or biased to a potential other than the tube potential. The acceleration tube can include an accelerator assembly. The accelerator assembly can be disposed in the common segment. The accelerator assembly can include a plurality of annular electrodes. The accelerator assembly can be coupled with bias circuitry configured to apply a bias voltage to the annular electrodes. The acceleration tube can include a substrate, disposed in the common segment and coupled with the accelerator assembly, the substrate defining multiple apertures configured to selectively transmit a portion of the charged particles incident on the substrate.

While the present disclosure generally pertains to the specific context of charged particle microscopy, and more specifically to electron microscopy, such descriptions are not intended to be limiting, and it is within the scope of the present disclosure that the apparatuses and methods disclosed herein may be applied in any suitable context.

### BRIEF DESCRIPTION OF THE DRAWINGS

The foregoing aspects and many of the attendant advantages of the present disclosure will become more readily appreciated as the same become better understood by reference to the following detailed description, when taken in conjunction with the accompanying drawings.

FIG. 1 is a schematic diagram illustrating an example charged particle beam system, in accordance with some embodiments of the present disclosure.

FIG. 2 is a schematic diagram illustrating an example charged particle multibeam system, in accordance with some embodiments of the present disclosure.

FIG. 3 is a schematic diagram illustrating an example charged particle multibeam system, in accordance with some embodiments of the present disclosure.

FIGS. 4A-4C are schematic diagrams illustrating an example separator, in accordance with some embodiments of the present disclosure.

FIG. 5 is a schematic diagram illustrating an example optical system, in accordance with some embodiments of the present disclosure.

FIG. 6A-6B are schematic diagrams illustrating a detail of the example optical system of FIG. 5, in accordance with some embodiments of the present disclosure.

FIGS. 7A-7B are schematic diagrams illustrating example optical systems including a third axis, in accordance with some embodiments of the present disclosure.

In the drawings, like reference numerals refer to like parts throughout the various views unless otherwise specified. Not all instances of an element are necessarily labeled to reduce clutter in the drawings where appropriate. The drawings are not necessarily to scale, emphasis instead being placed upon illustrating the principles being described.

### DETAILED DESCRIPTION

While illustrative embodiments have been illustrated and described, it will be appreciated that various changes can be made therein without departing from the spirit and scope of the disclosure. In the forthcoming paragraphs, embodiments of a charged particle beam system, components, and techniques for separating secondary charged particles emanating from a sample position. Embodiments of the present disclosure focus on electron microscopy and microanalysis and related systems in the interest of simplicity of description. To that end, embodiments are not limited to such systems, but rather are contemplated for charged particle beam systems where conventional techniques for detecting secondary charged particles are complicated by a multiplicity of primary charged particle beams and/or for samples that are ill-suited for approaches involving a bias voltage being applied to the sample surface. Similarly, while embodiments of the present disclosure focus on scanning electron microscopes, and multi-beam electron microscope systems in particular, additional and/or alternative beam systems are contemplated, including but not limited to focused ion beam systems, dual-beam systems, or the like.

Embodiments of the present disclosure include systems, methods, algorithms, and non-transitory media storing computer-readable instructions for charged particle imaging and microanalysis. In an illustrative example, a charged particle beam system can include an objective lens assembly, defining an aperture collocated with a first beam axis, an acceleration tube, defining a bifurcation, the acceleration tube including, a primary segment, a secondary segment, oriented and substantially concentric with a second beam axis at an angle, a, relative to the first beam axis, and a common segment, disposed at least partially in the aperture. The charged particle beam system can also include a separator, including one or more charged-particle optical elements disposed in the common segment and configured to apply a deflection force to electrons having a negative velocity in a first direction, the first direction being substantially aligned with the common segment of the acceleration tube. The deflection force can redirect the electrons toward a second direction substantially aligned with the second beam axis. Advantageously, embodiments of the present disclosure improve the sensitivity, robustness, and flexibility of operation conditions for multi-beam charged particle systems, while also permitting the analysis of non-conducting and/or dielectric samples that are ill-suited for current systems and/or techniques.

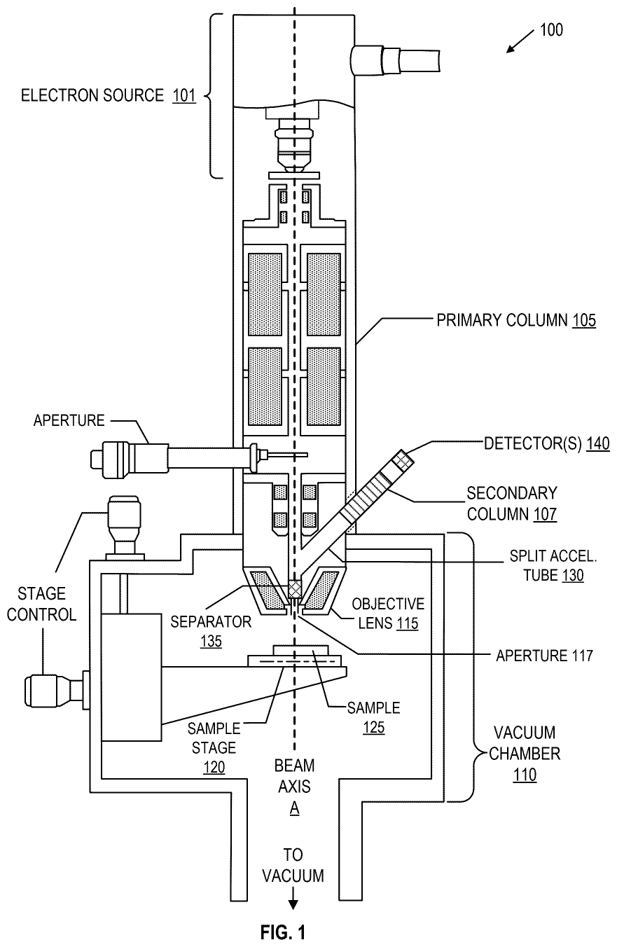

FIG. 1 is a schematic diagram illustrating an example charged particle beam system, in accordance with some embodiments of the present disclosure. Example system 100 includes multiple sections including an electron source 101, a primary column 105, and a vacuum chamber 110. The electron source 101 includes high-voltage supply components, vacuum system components, and an electron emitter configured to generate a beam of electrons that is accelerated into the beam column 105. The beam column 105, in turn, includes electromagnetic lens elements that are configured to shape and form the beam of electrons from the electron source into a substantially circular beam with a substantially uniform profile transverse to a beam axis A, and conditions the beam to be focused onto a sample 125 by an objective lens assembly 115. The objective lens assembly 115 defines an aperture 117. The example system 100 further includes a split accelerator tube 130 defining a bifurcation, a portion of which is aligned with the primary column 105 and another portion of which is aligned with a secondary column 107.

The beam of electrons is typically characterized by a beam current and an accelerating voltage applied to generate the beam, among other criteria. The ranges of beam current and accelerating voltage can vary between instruments and are typically selected based on material properties of the sample or the type of analysis being conducted. Generally, however, in a scanning electron microscope, beams of electrons can be characterized by an energy from about 0.1 keV (e.g., for an accelerating voltage of 0.1 kV) to about 50 keV and a beam current from picoamperes to microamperes.

The vacuum chamber 110 and/or the beam columns 105-107 can include multiple detectors for various signals, including but not limited to secondary electrons generated by interaction of the beam of electrons and the sample, x-ray photons (e.g., EDAX), other photons (e.g., visible and/or IR cameras), and/or molecular species (e.g., TOF-SIMS), as described in more detail in reference to FIG. 1B. The vacuum chamber 110 can also include a sample stage 120 that can be operably coupled with a multi-axis translation/rotation control system, such that the sample 125 can be repositioned relative to the beam axis A, as an approach to surveying and/or imaging the sample 125. To that end, one or more charged particle and/or radiation sensors can be disposed in the vacuum chamber 110 and/or in the beam column 105 and configured to detect characteristic signals emanating from the sample (e.g., reflected and/or transmitted).

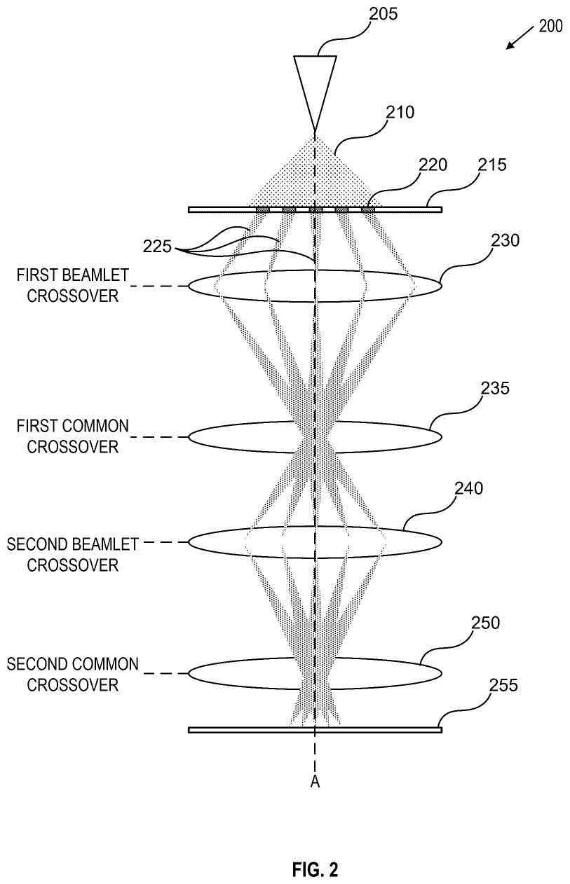

Example charged system 100 is illustrated as a single-beam SEM instrument to focus description on components of the example system 100. In some embodiments, example system 100 can incorporate additional and/or alternative components to include an ion-beam source (e.g., a focused ion beam, or FIB as part of a dual-beam system) adapted, for example, to modify a sample or for microanalysis. Similarly, the charged system 100 can include a source of photons, such as a laser or other electromagnetic radiation source. As described in more detail in reference to FIG. 2, embodiments of the present disclosure include components of example system 100 that enable the electron source 101 to generate multiple beamlets of charged particles. Advantageously, multiple beamlets can parallelize charged particle microscopy and microanalysis, increasing throughput and efficiency of analyzing large samples.

Secondary electron detection in multibeam microscopy samples implicates several application-specific constraints. In particular, resolving secondary electron information from individual beamlets represents a significant challenge, arising from the tendency of secondary electron beamlets to overlap in space, which presents significant challenges in detection of distinct secondary electron signals. To that end, embodiments of the present disclosure include a split acceleration tube 130 that extends at least partially into the aperture 117 of the objective lens assembly 115. The split acceleration tube 130 can impart energy (e.g., accelerate) secondary electrons that emanate from the sample 125 into the split acceleration tube 130 and through a separator 135. The separator 135 can be configured to redirect secondary electrons into a secondary column 107, including charged particle optical elements. The secondary column 107, in turn, can form, redirect, shape, focus, defocus, and/or project (among other transformations) the secondary electrons to impinge on one or more detectors 140 coupled with the secondary column 107.

In reference to the forthcoming paragraphs and FIGS. 2-7, various aspects, details, features, and/or embodiments of the example system 100 and other charged particle beam systems are elaborated and described. In some embodiments, the split acceleration tube 130 is a physical, material, object (e.g., a dielectric tube) that defines a bifurcation and a common segment. In some embodiments, the common segment is at least partially disposed in the aperture 117 of the objective lens assembly 115. In this way, secondary electrons, generated at or near the surface of the sample 125, can be accelerated into the common segment and separated from primary electrons of the beam (or beamlets) and directed toward the secondary column 107 and the detector(s) 140. Advantageously, accelerating the secondary electrons to a relatively high voltage can reduce chromatic and geometrical aberrations of the separator and the projection system. Accelerating the secondary electrons reduces the relative energy spread, collimates the beamlets, and reduces the extent of cross-talk between beamlets. In contrast to conventional techniques addressed at multi-beam electron microscopy that apply a bias to the sample 125 itself, as an approach to accelerating electrons away from the sample 125 and into the column optics, embodiments of the present disclosure are enabled for samples 125 that are non-conductive or otherwise sensitive to applied voltages on the kilovolt scale (e.g., insulating samples, nanoparticle samples that might otherwise detach from the sample surface and be repelled into the column, etc.).

FIG. 2 is a schematic diagram illustrating an example charged particle multibeam system 200, in accordance with some embodiments of the present disclosure. The example system 200 includes a charged particle source 205 that is configured to generate a highly divergent electron beam 210, an aperture lens array (ALA) 215, defining multiple apertures 220 through which the beam 210 is transformed into multiple beamlets 225. The beamlets 225 pass through a first condenser lens 230, disposed substantially at a point on the beam axis A corresponding to a first beamlet crossover. The first condenser lens 230 redirects the beamlets 225 towards a first common crossover at which a second condenser lens 235 is disposed. The diverging beamlets that emerge from the second condenser lens 235 are individually convergent and focus to a second beamlet crossover at which a third condenser lens 240 is disposed. Downstream of the third condenser lens 240 on the axis A, an objective lens 250 is disposed at a second common crossover of the beamlets 225, between the third condenser lens 240 and a sample position 255. In some embodiments, additional and/or alternative optics are included and the beamlets 225 can exhibit more or fewer crossovers. The beam axis A can include straight segments and/or curved segments.

Beamlets 225 have an average energy consistent with typical energies for primary electrons (e.g., from about 1 kV to about 100 kV), and are directed toward discrete regions of a sample (e.g., the sample 125 of FIG. 1). Multi-beam microscopy and microanalysis includes scanning the beamlets 225 across the surface of the sample using a scan pattern for each beamlet 225 that, in sum, covers a relatively large region of the sample, as compared to typical single beam systems. In this way, secondary electron imaging of the relatively large region of the sample can be undertaken by processing of detector data (e.g., stitching sub-images or “tiles” together to form a larger composite image) in a relatively short time, without moving the sample relative to the beam axis A as frequently as would otherwise be done for single-beam systems.

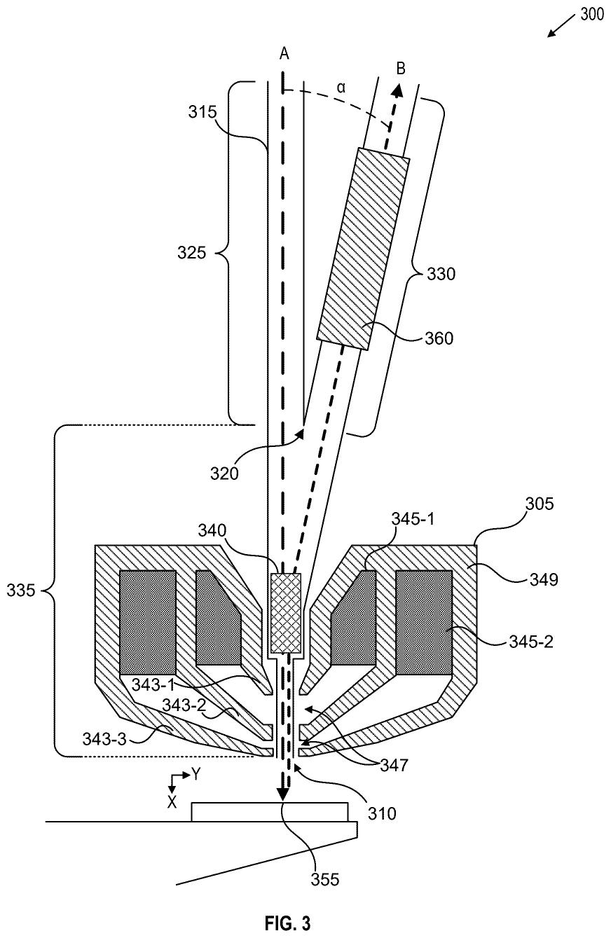

Multi-beam techniques introduce several significant technical challenges, however, concerned with separating secondary electrons generated by the interaction of each respective beamlet 225 with the sample, and generating distinct secondary electron detector data for each respective beamlet 225. To that end, example system 200 can include a pixelated or otherwise segmented detector and optics configured to project the secondary electrons onto the detector. This technique is not shown in FIG. 2, but is described in reference to the forthcoming FIGS. 3-7.

As mentioned in reference to FIG. 1, cross-talk between beamlets in a multi-beam system can be addressed by accelerating the electrons (e.g., thereby reducing the relative energy spread of the beamlets). To that end, the example multibeam system 200 can accelerate the secondary electrons emanating from the sample position 255 in several ways. A first approach to accelerating the secondary electrons includes applying a DC bias to the sample (e.g., on the order of 1 kV-10 kV), and use the electric field to repel secondary electrons away from the sample and towards a detector (e.g., into secondary column 107 of FIG. 1). A second approach includes attracting secondary electrons emanating from the sample position 255 using an acceleration tube, as illustrated in FIG. 1 and described in more detail in reference to FIGS. 3-7. Advantageously, accelerating the secondary electrons to a higher average energy reduces the spatial overlap in a detector plane, or “crosstalk,” between the channels (e.g., data from respective beamlets 225). Further, applying the second, acceleration tube approach, in accordance with embodiments of the present disclosure, obviates the significant effects of applying a strong bias to dielectric and/or insulating and/or semiconductor samples, which are ill-suited to the first approach.

FIG. 3 is a schematic diagram illustrating an example charged particle optical system 300, in accordance with some embodiments of the present disclosure. The example system 300 is an embodiment of at least part of the example system 100 of FIG. 1. The example system 300 includes an objective lens assembly 305, defining an aperture 310 collocated with a first axis A, and an acceleration tube 315, defining a bifurcation 320. The acceleration tube 315 includes a primary segment 325, a secondary segment 330, and a common segment 335. The example arrangement also includes a separator 340 and a secondary column 360 (e.g., secondary column 107 of FIG. 1).

In some embodiments, the primary segment 325 is substantially concentric with the first axis A. Similarly, the aperture 310 can be substantially concentric with the first axis A. In this context, “substantially concentric” refers to an orientation about the first axis A, such that electromagnetic fields, used to form, shape, redirect, deflect, or otherwise transform a beam of charged particles that is substantially aligned with the first axis A, can be substantially axis-symmetric about the first axis A. For example, one or more electromagnetic lenses of the objective lens assembly 305 can generate substantially axis-symmetric fields, where the beam axis A serves as the axis of symmetry. It is understood, however, that the axis of symmetry can deviate from the beam axis A (e.g., not perfectly coincident) within an allowable tolerance.

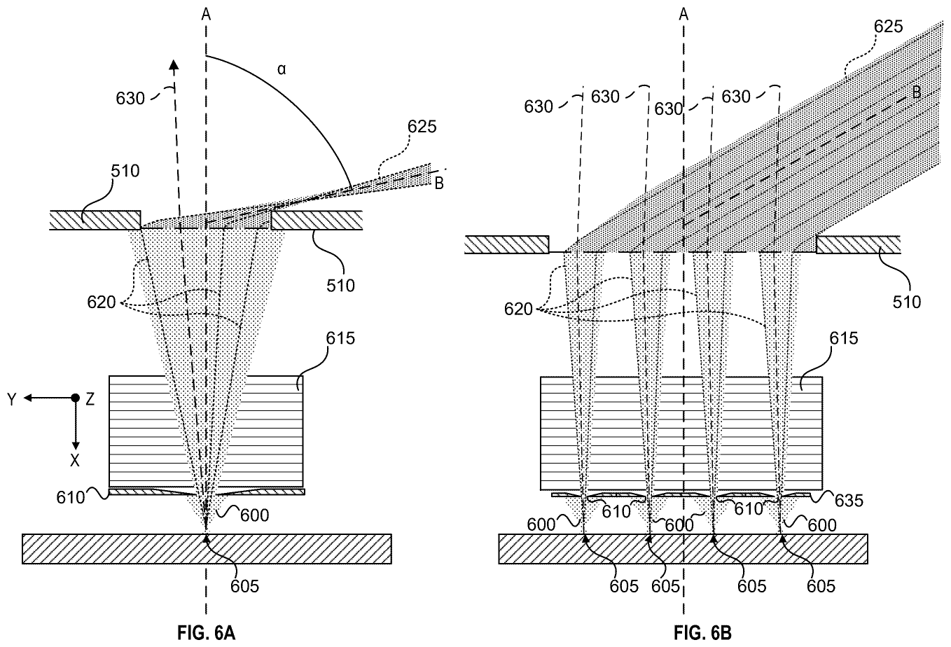

In some embodiments, the secondary segment 330 is oriented with and substantially concentric with a second axis B. The second axis B can be oriented at an angle, α, relative to the first axis A. The angle, α, can be greater than about 5 degrees, including sub-ranges, fractions, and interpolations thereof. As described in more detail in reference to FIG. 6, an angle smaller than about 5 degrees can implicate space constraints, induce electromagnetic interference between primary beam particles (e.g., primary electrons) and measured particles (e.g., secondary electrons) that distorts detector data, and impair the operation of the separator 340. For example, angle, α, can be about 20 degrees, about 22 degrees, about 24 degrees, etc.

The common segment 335 can include portions of the first axis A and the second axis B, between the bifurcation 320 and the separator 340. Between the separator 340 and a sample position 355, the common segment 335 can be substantially concentric with the first axis A. The common segment 335 can be disposed at least partially in the aperture 310. In the example system 300, the separator 340 is disposed at least partially in the aperture 310 of the objective lens assembly 305, as well.

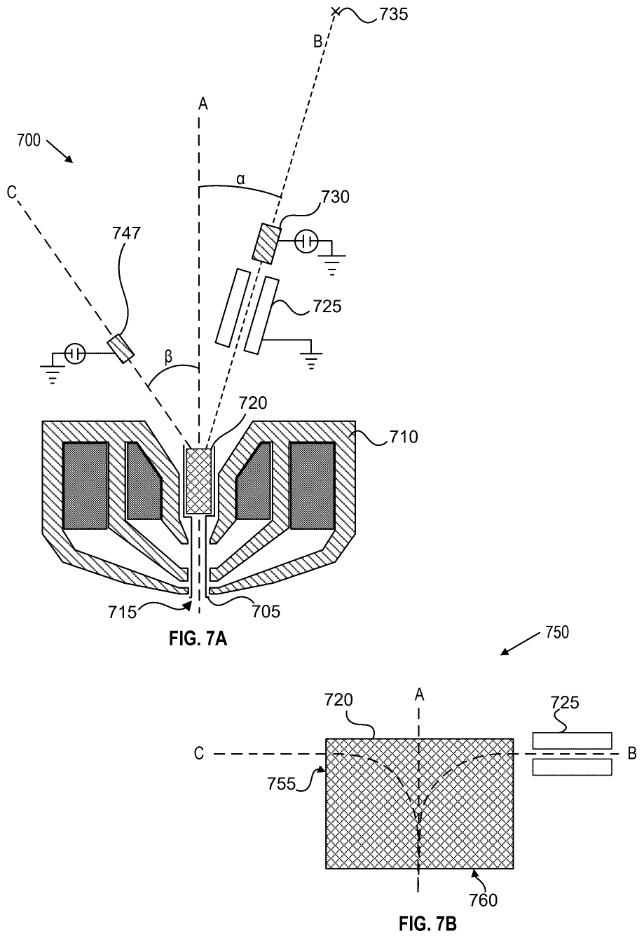

The acceleration tube 315 can be a physical component or an intangible “virtual” tube. To that end, the acceleration tube 315 can define a space within which charged particle optical components (e.g., beam limiting apertures, lenses, stigmators, etc.) are biased to a given voltage. Components outside the space of the acceleration tube 315 can be coupled to ground or other voltage. In an illustrative example, magnetic optics (e.g., used as lenses) can be disposed outside the acceleration tube 315 and coupled with a ground potential. In the example shown in FIG. 3, the example system 300 includes the secondary column 360, disposed along the secondary beam axis B. The secondary column 360 can include one or more electron optical elements disposed in the inner space of the acceleration tube 315 and coupled with electrical bias circuitry configured to apply a potential to the electron optical elements, as described in more detail in reference to FIG. 7.

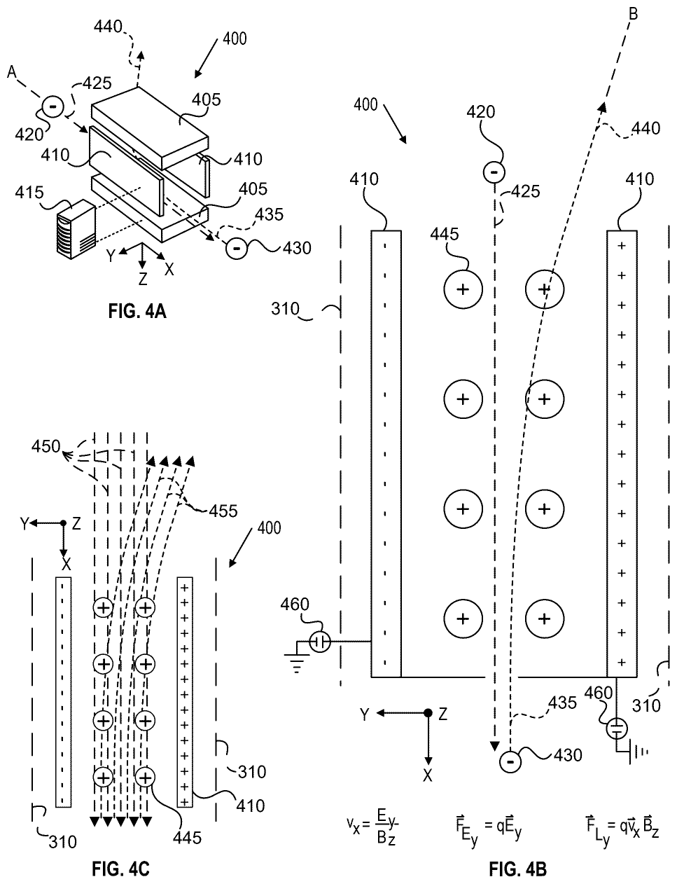

The separator 340 can be an assembly of one or more charged-particle optical elements configured to apply a deflection force in a directionally-specific way. To that end, the separator 340 can be disposed in the common segment and configured to apply the deflection force to electrons having a negative velocity in a first direction, as described in more detail in reference to FIGS. 4A-4C. In the context of the example system 300, the first direction is substantially aligned with the common segment of the acceleration tube and with the first axis A and directed toward the sample position 355. In turn, the deflection force can redirect electrons having a negative velocity in the first direction toward a second direction substantially aligned with the second axis B, as described in reference to FIG. 6.

The acceleration tube 315 can be configured to increase a magnitude of the negative velocity of the electrons in the first direction. In this context, “magnitude of the negative velocity” refers to accelerating electrons (e.g., by electrostatic attraction and/or repulsion) in a given direction, without a change in sign of a velocity component in a given coordinate. In some embodiments, the acceleration tube 315 includes multiple annular electrode elements (shown in FIG. 6), separated by an insulating or dielectric medium (e.g., ceramic spacer(s), vacuum, etc.) that are electrically coupled with a direct current voltage source (e.g., a high-voltage supply) that is configured to bias the electrode elements. The annular electrode elements can be arranged to generate a substantially linear electric field, oriented in the first direction and having a magnitude such that the secondary electron is attracted into the acceleration tube 315 and accelerated against the first direction.

In an illustrative example, a secondary electron can be generated by a sample under irradiation by a beam of primary charged particles substantially aligned with the beam axis A and directed in the first direction. In an orthogonal coordinate space defined relative to the first direction (labelled ‘X’ and ‘Y’ in FIG. 3) the secondary electron can leave the surface of the sample with a velocity having a negative component in the first direction and a nonzerovelocity in a normal direction (‘Y’ or ‘Z’), which can also be referred to as a lateral direction. The secondary electron can be attracted into the electric field of the acceleration tube 315, accelerated against the first direction, or the ‘−X’ direction, and drawn into the separator 340.

Advantageously, accelerating electrons using the acceleration tube 315, disposed at least partially in the aperture 310 of the objective lens assembly 305, improves the performance of the separator 340, at least in part by reducing the interference between secondary electrons that impairs spatial resolution of signals in multibeam operation and also at least in part by reducing the sensitivity of the separator 340 to velocity component in the normal, ‘Y,’ direction by significantly increasing the magnitude of the velocity component in the first, ‘X,’ direction, making the ‘Y’ component a smaller proportion of the total energy of the electron. In contrast to alternative approaches for accelerating electrons, such as biasing the sample stage or the sample itself, the acceleration tube 315, located at least partially in the aperture 310 and separate from the sample stage, can be used with non-conducting, semiconducting, and/or composite samples (e.g., integrated circuit samples) or with active/operating semiconductor devices which can be incompatible with biasing (e.g., are constrained by being grounded).

The objective lens assembly 305 can include a multiple-gap objective lens. As illustrated in FIG. 3, a multiple-gap objective lens includes a magnetic lens configured to direct a charged particle beam to a sample location in a focal plane. The magnetic lens can include a plurality of pole pieces 343 defining at least two axial gaps 347 and at least two independent coils 345 in respective communication with the at least two axial gaps 347 and configured to generate magnetic fields such that the magnetic lens operates as a single objective lens with variable main objective plane. The variable main objective plane permits selective adjustment of a magnification of the charged particle beam at the focal plane without immersing the sample location in the magnetic fields produced by coils of the magnetic lens.

The magnetic lens can include a lens body 349, a first coil 345-1 supported by the lens body, and a second coil 345-2 supported by the lens body. The first coil 345-1 is configured to generate a first magnetic field and the second coil 345-2 is configured to generate a second magnetic field. The lens body 349 defines the aperture 310 configured to receive a charged particle beam passing through the magnetic lens, a first pole piece 343-1, a second pole piece 343-2, and a third pole piece 343-3. The first pole piece 343-1 can extend circumferentially around the central bore. The second pole piece 343-2 can extend circumferentially around the aperture 310 and can be at least partially concentric with the first pole piece 343-1, with an inner radius that is larger than that of the first pole piece 343-1. Similarly, the third pole piece 343-3 can extend circumferentially around the aperture 310 and can be at least partially concentric with the first pole piece 343-1 and the second pole piece 343-2, with an inner radius that is larger than that of the first pole piece 343-1 and the second pole piece 343-2.

In some embodiments, however, the objective lens assembly 305 includes a single-gap magnetic lens and an immersion lens, or a single-gap magnetic lens and an electrostatic lens. Advantageously, the multiple-gap objective lens described in FIG. 3 improves the performance of the example system 300 overall, relative to the alternative objective lens assemblies 305, by broadening the operational window of accelerating voltage (e.g., primary beam energy), beam current, and working distance, among other operating parameters of a charged particle beam system. In this way, the example system 300 can be more readily adapted for microscopy and microanalysis of a wider range of samples that implicate different operating parameters.

The objective lens assembly 305 can be configured to generate one or more magnetic fields that deflect the charged particles of the charged particle beam to direct and/or focus the charged particle beam to a localized region at the sample position 355. In an example in which the charged particle beam comprises a plurality of beamlets, the objective lens assembly 305 can be configured to direct the beamlets to respective spaced-apart focus locations on a plane of the sample position 355. In some examples, the sample position 355 corresponds to a focus location of the charged particle beam. Additionally or alternatively, the sample position can correspond to a location (e.g., a plane) corresponding to a minimum characteristic beam size of the charged particle beam(s) (e.g., a minimum beam width or diameter) and/or an optimal focus condition. In this manner, as used herein, the sample position 355 can represent a location (e.g., a point and/or a plane) at which a sample and/or a portion thereof (e.g., an exposed surface of the sample) can be positioned during operative use of the example system 300, regardless of whether a sample is present at the sample position 355.

The first coil 345-1 can be configured to generate a first magnetic field and the second coil 345-2 can be configured to generate a second magnetic field, each of which can act upon (e.g., exert a Lorentz force upon) particles of the charged particle beam traveling through the objective lens assembly 305 to focus the charged particle beam toward the sample position 355. In various examples, the objective lens assembly 305 is configured such that, when the objective lens assembly 305 generates each of the first magnetic field and the second magnetic field, the first magnetic field and the second magnetic field overlap (e.g., spatially) to form a total magnetic field that is a sum of the first magnetic field and the second magnetic field.

The first magnetic field can be characterized by a first field magnitude at each point in space around the first coil 345-1 and the second magnetic field can be characterized by a second field magnitude at each point in space around the second coil 345-2. Thus, the total magnetic field may be characterized by a total field magnitude at each point in space around the first coil 345-1 and the second coil 345-2 that is a sum of the first field magnitude and the second field magnitude at that point. The first magnetic field and the second magnetic field may be at least partially overlapping within the aperture 310 of the objective lens assembly 305 such that a charged particle beam passing through the aperture 310 converges, in response to force of the total magnetic field, toward a focal point.

In various examples, characteristics and/or operation of the objective lens assembly 305 can be described in terms of the first magnetic field alone, the second magnetic field alone, the first magnetic field and the second magnetic field, and/or the total magnetic field. Unless stated otherwise, descriptions referencing the first magnetic field, the second magnetic field, and/or the total magnetic field generally pertain to examples in which the referenced magnetic field has a nonzero magnitude.

Similar to typical magnetic lenses of the current art, the objective lens assembly 305 can be configured to selectively adjust the focal length and/or a location of the focus location of the charged particle beam via adjustment of a ratio of the first field magnitude of the first magnetic field and the second field magnitude of the second magnetic field.

As described in more detail below, the lens body 349 can be configured to localize the total magnetic field away from the sample position 355. In particular, the lens body 349 can be configured such that, when the objective lens assembly 305 operates to generate the total magnetic field, the charged particle beam passing through the lens body 349 is subject to each of the first magnetic field and the second magnetic field, while each of the first magnetic field and the second magnetic field are confined and/or localized to a region away from the sample position 355.

The objective lens assembly 305 can be configured to adjust a position of a main objective plane through adjustment of the ratio of the first field magnitude to the second field magnitude. Advantageously, adjusting the position of the main objective plane also enables adjustment of the magnification of an optical system including the objective lens assembly 305 while allowing the working distance of the objective lens assembly 305 to remain unchanged (or to change by a small amount) and while shielding and/or isolating a sample at or near the sample position 355 from the total magnetic field.

In this way, the objective lens assembly 305 can be configured such that a sample is at least substantially isolated from each of the first magnetic field and the second magnetic field during operative use while retaining the ability to selectively adjust aperture angle and optical column magnification without using an immersion lens. Accordingly, the objective lens assembly 305 can be used in conjunction with magnetically sensitive samples and/or samples that otherwise would be ill-suited for use with an immersion magnetic lens. As another advantage, the multi-gap magnetic lens illustrated in FIG. 3 also improves performance of the split acceleration tube 315 for a broad range of operating conditions and for multi-beam systems, based at least in part on the relatively small or negligible magnetic fields in the vicinity of the sample position 355 having an attenuated effect on secondary electrons.

To that end, the objective lens assembly 305 may be configured to localize the total magnetic field to any suitable degree to yield a relatively small and/or negligible magnetic field at the sample position 355. In some examples, the localization of the total magnetic field may be characterized and/or quantified via a comparison of the respective magnitudes of the magnetic fields within the aperture 310 and at the sample position 355. For example, the total magnetic field may be characterized by a maximum focusing field amplitude that represents a maximum amplitude of the total magnetic field at any point within the aperture 310, and a magnitude of the total magnetic field as measured at the sample position 355 can be at most 5% of the maximum focusing field amplitude, at most 2% of the maximum focusing field amplitude, at most 1% of the maximum focusing field amplitude, at most 0.5% of the maximum focusing field amplitude, and/or at most 0.1% of the maximum focusing field amplitude.

The lens body 349 can have any suitable structure and/or configuration for localizing the total magnetic field as described herein. For example, and as shown in FIG. 3, the lens body 349 can include a first pole piece 343-1, a second pole piece 343-2, and a third pole piece 343-3, each of which extends at least partially circumferentially around the aperture 310. The second pole piece 343-2 can be at least partially concentric with the first pole piece 343-1, and the third pole piece 343-3 can be at least partially concentric with the second pole piece 343-3. Objective lens assembly 305 represents an example in which each of the first coil 345-1, the second coil 345-2, the first pole piece 343-1, the second pole piece 343-2, and the third pole piece 343-3 are rotationally symmetrical and fully concentric with the first axis A. In some embodiments, however, the first pole piece 343-1, the second pole piece 343-2, and/or the third pole piece 343-3 can be described by rotational solids that extend partially around the first axis A.

FIGS. 4A-4C are schematic diagrams illustrating an example separator 400, in accordance with some embodiments of the present disclosure. The example separator 400 of FIGS. 4A-4C represents an embodiment of at least part of the separator 135 of FIG. 1 and/or the separator 340 of FIG. 3. The example separator 400 includes one or more charged particle optical elements forming a Wien filter, shown schematically in FIG. 4A, which includes magnetic elements 405 and electrostatic elements 410, arranged and configured to generate orthogonal magnetic and electric fields, respectively.

The one of more optical elements can be operably coupled with control circuitry 415 that configure the Wien filter to apply negligible or substantially no deflection force to primary particles 420 at about a given velocity in a first direction (‘X’ in FIGS. 4A-4C). The primary particles 420, in the context of an electron beam system of the present disclosure (e.g., example system 100 of FIG. 1) can be generated in one or more beams of electrons assuming a general trajectory 425 that is aligned with a beam axis of the system (e.g., first axis A) and having a positive velocity in the first direction. In contrast, the Wien filter can be configured to apply a deflection force to charged particles that have an velocity in the first direction that deviates from the given velocity ‘vₓ.’ As an illustrative example, secondary particles 430 (e.g., secondary electrons), having a negative velocity component in the first direction and generally a much smaller magnitude of the velocity in the first direction, can be deflected from an initial trajectory 435 to a second trajectory 440.

The deflection force can result from a Lorentz force, induced by the motion of a charged particle through a magnetic field 445, being partially balanced an opposing electrostatic force applied by an electric field, each acting normal to the first direction, X, (‘Y’ in FIGS. 4A-4C). For a Wien filter, the expressions below describe the respective forces acting on the charged particle (e.g., a primary electron, a secondary electron, etc.):

$${F}_{{E}_{y}} = q {E}_{y} \qquad ( 1 )$$

$${F}_{{L}_{y}} = {qv}_{x} {B}_{z} \qquad ( 2 )$$

$${v}_{x} = \frac{- {E}_{y}}{{B}_{z}} \qquad ( 3 )$$

Equation (3) describes the velocity in the first direction in which the Lorentz force and the electrostatic force are equal and opposite (e.g., Eq. (1)+Eq. (2)=0), for which the simple derivation has been omitted. In this way, embodiments of the present disclosure include a Wien filter for which the electric field strength and the magnetic field 445 strength are configured to satisfy the condition of Eq. (3) for primary particles 420 of the incident beam(s). The resulting imbalance of forces on secondary particles 430, directed into the example separator 400 by the acceleration tube 315, redirects the trajectory 440 of the secondary particles 430 toward the second axis B. The example of a single particle trajectory in each direction is shown in FIGS. 4A-4B. FIG. 4C, in contrast, illustrates an embodiment where multiple beamlets 450 are directed in the first direction, each substantially aligned in the first direction, ‘X,’ and multiple secondary particle trajectories 455, having a negative velocity in the first direction.

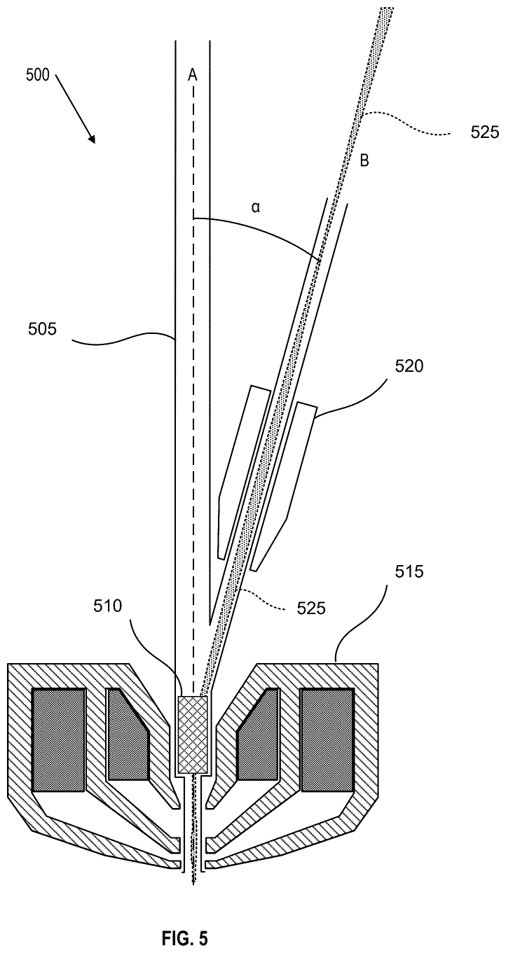

Assuming uniform magnetic field 445 and uniform electric field in a given Y-Z plane, two charged particles in parallel trajectories should experience equal deflection force applied by the magnetic field. In this way, primary beamlets 450 are not deflected when the fields satisfy Eq. (3), and secondary particles 430 follow parallel deflected trajectories 455, assuming that the secondary particles have substantially equal velocity in the first direction. The secondary particle trajectories 455 represent a simplification, assuming a substantially Dirac-distribution of energy (e.g., having a narrowed relative energy spread achieved in part through acceleration). Detailed analysis is provided in reference to FIGS. 5-6, below.

Embodiments of the present disclosure include control circuitry 415, operatively coupled with the example separator 400, and configured to maintain the requisite electric and magnetic fields to satisfy Eq. (3) for the energy of the primary particles 420. The control circuitry 415 can include elements of a control system encoded in software, embodied in hardware, and/or provided as firmware, by which the control circuitry 415 can automatically (e.g., without human intervention), pseudo-automatically (e.g., with human initiation), and/or manually (e.g., with human control), modify, set, or otherwise specify a set of operating conditions for the separator 400. In some embodiments, the control circuitry 415 can be operably coupled with other systems and/or subsystems of a charged particle beam system (e.g., system 100 of FIG. 1, system 300 of FIG. 3, etc.) such that the control circuitry 415 can determine and implement operating parameters that satisfy Eq. (3) by referencing operating parameters of other systems (e.g., by reading the accelerating voltage of the source).

As described in reference to FIG. 3 and FIG. 7A, bias circuitry 460 can be configured to bias to one or more elements of the separator at about the voltage of the acceleration tube 315. In this way, optics and other components of the systems of the present disclosure can function without interfering with the trajectories of charged particles. In an illustrative example, the negative electrode(s) of the example separator 400 can be negative relative to the positive electrode(s), such that both electrodes are positively biased. Similarly, the positive electrode(s) of the example separator 400 can be positive relative to the negative electrode(s), such that both electrodes are negatively biased. The magnetic field 445 can be generated by magnets and/or electromagnets placed outside the acceleration tube 315. Alternatively, the magnets and/or electromagnets can be disposed within the acceleration tube 315 and coupled with bias circuitry 460 as well.

FIG. 5 is a schematic diagram illustrating an example optical system 500, in accordance with some embodiments of the present disclosure. Example system 500 includes an embodiment of the systems of FIGS. 1-4B (e.g., example system 100 if FIG. 1 and/or example system 300 of FIG. 3). The example optical system 500 includes a split acceleration tube 505, a separator 510, an objective lens assembly 515, and a projection system 520. The projection system 520 is an example embodiment of the secondary column 107 of FIG. 1 and/or the secondary column 360 of FIG. 3. The split acceleration tube includes a bifurcation (e.g., bifurcation 320 of FIG. 3) that defines a common segment (e.g., common segment 335 of FIG. 3), disposed at least partially in an aperture of the objective lens assembly (e.g., aperture 310 of FIG. 1), the separator being at least partially disposed in and/or about the common segment. The split acceleration tube 505 further includes a primary segment (e.g., primary segment 325 of FIG. 3) and a secondary segment (e.g., secondary segment 330 of FIG. 3), oriented in substantial alignment with a first axis A and a second axis B, respectively, where the second axis is oriented relative to the first axis A by an angle α.

The projection system 520 can include various charged particle optical elements, such as electromagnetic lenses. The projection system 520 can be configured to form, shape, deflect, and/or collimate one or more beams of charged particles that propagate from the separator 510 to the secondary segment of the split acceleration tube, and toward a detector (e.g., detector(s) 140 of FIG. 1). As described in more detail in reference to FIGS. 1-4B, charged particles emanating from the sample position (e.g., sample 125 of FIG. 1, sample position 355 of FIG. 3) can be described by an energy distribution that is based at least in part on the energy of the incident primary charged particles of the incident beam(s) and at least in part on the composition and surface topography of the sample, among other factors. To that end, the “beam” 525 of charged particles shown in FIG. 5, represented in dotted lines with a hatched fill, represents a region within which it is most likely to detect charged particles. As described in more detail in reference to FIG. 6, charged particles (e.g., secondary electrons) can be incident on the separator 510 with a range of entry angles and energies. Advantageously, the acceleration tube 505 can reduce the variance/standard deviation of energy of the charged particles entering the separator, thereby narrowing the distribution of energies in the beam(s) 525 entering the secondary segment of the acceleration tube 505. When considering the case of a Wien filter, a narrower energy distribution with respect to velocity in the first direction provides a narrower distribution of deflection force and better performance of the projection system 520.

The projection system 520 can include one or more electron optical elements disposed external to the acceleration tube 505. As described in more detail in reference to FIGS. 1, 4, and 7, the acceleration tube 505 can be a physical tube or a “virtual” tube, where individual components are biased to the relatively high voltage of the acceleration tube, as compared to other components, which can be grounded or held at a relatively lower voltage. In some embodiments, components that function by generating a magnetic field through which charged particles are directed (e.g., magnetic projector lenses) are disposed external to the acceleration tube 505. In this context, “external” is a term used to refer to either a physical location outside a physical acceleration tube or at a relatively low voltage or substantially no applied voltage, relative to the acceleration tube voltage, and at a distance from the beam(s) of charged particles such that the element(s) do not interfere with the shape and/or direction of the beam(s).

FIGS. 6A-6B are schematic diagrams illustrating a detail of the example optical system 500 of FIG. 5, in accordance with some embodiments of the present disclosure. FIGS. 6A-B omit the optical lens assembly 515 and the projection system 520 to focus description on components of the acceleration tube 505 and the separator 510. FIGS. 6A-B describe optical transformations applied to a flux of charged particles 600 emanating from a sample position 605, having a negative velocity in a first, ‘X,’ direction. The components of the acceleration tube include an entrance aperture 610 and an accelerator assembly 615.

The charged particles 600 can include secondary electrons 620, backscattered electrons 630, Auger electrons, secondary ions, backscatter ions, or the like, including combinations thereof. Embodiments of the current disclosure include optical components 510, 610, and 615 being configured to select secondary electrons 620 having an energy and/or or velocity within a given range, such that the secondary electrons 620 are redirected by the separator 510 toward a second axis B (e.g., second axis B of FIGS. 1, and/or 3-5) and defining one or more beams 625 of secondary electrons. Backscattered electrons 630, shown as an example trajectory in a dashed line, typically can be characterized as having an energy that is similar or substantially equal to that of primary electrons of the incident beam. For that reason, backscattered electrons 630 that pass the aperture 610 can have a significantly higher energy (e.g., about an order of magnitude higher) at the separator 510 than secondary electrons 620. Backscattered electrons 630 are unlikely, for that reason, to be redirected toward the second axis B such that backscattered electrons 630 are introduced to the projector system 520, instead being deflected less than secondary electrons 620. In this way, the separator 510 can select secondary electrons 620 to be directed toward the secondary column (e.g., secondary column 107 of FIG. 1).

The example shown in FIG. 6A is for a single incident beam, but embodiments of the present disclosure include components of the acceleration tube (e.g., acceleration tube 315 of FIG. 3, 505 of FIG. 5, etc.) being configured for use in multi-beam systems, illustrated in FIG. 6B. FIG. 6B is illustrated with four beamlets, but embodiments of the present disclosure can be configured to accommodate more or fewer beamlets. In an example of a multi-beam system, as described in reference to FIG. 2, individual beamlets (e.g., beamlets 225 of FIG. 2) can be directed to respective sample positions 605 on a sample surface that can be mutually separated by about a micrometer or more. Without being bound to a specific physical mechanism of operation, secondary electrons 620 from a given sample position 605 can travel into the accelerator assembly 615 with little or substantially no lateral cross-talk between neighboring sample positions 605, based at least in part on the relatively large distance between sample positions 605 when compared to the angular distribution of secondary electron 620 emission.

Embodiments of the present disclosure include a substrate 635 defining multiple apertures 610, each oriented to substantially coincide with a beamlet (e.g., having a region defined by the scan extent of the beamlet be substantially centered in the aperture 610) and serving the purpose of limiting incident charged particles 600 to a subset of initial trajectories out of the entire range of initial trajectories from the sample position 605. In this way, cross-talk between neighboring beamlets can be limited.

In FIGS. 6A-6B, the first axis A (e.g., first axis A of FIGS. 1, and/or 3-5) represents a hypothetical trajectory of a beam of primary charged particles (e.g., electrons, ions, etc.) that stimulate the reemission of the charged particles 600 toward the aperture 610 and the accelerator assembly 615 of the acceleration tube. The accelerator assembly 615 can include one or more annular conductors (e.g., conductive metal ring elements) that are mutually separated by a dielectric or non-conducting spacer, scaffold, housing, etc. The accelerator assembly 615 can include and/or be operably coupled with bias circuitry. The bias circuitry can be configured to apply a bias voltage to the annular conductor(s) or a subset of the annular conductors, such that the combined electric field is substantially parallel within an inner volume defined by the annular conductors and substantially aligned with the first axis A. The electric field in the accelerator assembly 615 can be oriented relative to the first direction, ‘X,’ such that charged particles 600 emanating from the sample position are accelerated to ward the separator 510. In the example of secondary electrons 620, the electric field of the accelerator assembly 615 can be oriented with the first direction.

The accelerator assembly 615 can be configured to accelerate an electron from an energy on the order of about 10 eV to about 100 eV to an energy on the order of about 1 keV to about 10 keV, including subranges, fractions, and interpolations thereof. To that end, the electric field strength generated by the accelerator assembly 615 can be from about 100 keV/m to about 10000 keV/m, including subranges, fractions, and interpolations thereof. As described in more detail in reference to FIG. 5, a smaller acceleration can increase crosstalk by deflecting charged particles too greatly and can reduce the operating window of the separator, based at least in part on the relatively large difference in energy between the primary beam particles and the charged particles 600 that enter the separator 510 from accelerator assembly 615. In contrast, a larger acceleration can reduce the effectiveness of the separator 510 to redirect the charged particles 600 toward the second axis B, by bringing the charged particles 600 closer to the energy for which the separator has been calibrated (e.g., the primary beam energy in the first direction).

FIGS. 7A-7Bare schematic diagrams illustrating an example charged particle optics system 700 including a third axis C, in accordance with some embodiments of the present disclosure. Example system 700 represents an embodiment of example system 100 of FIG. 1, example system 300 of FIG. 3, example system 500 of FIG. 5, etc., for which optical elements are included to define the third axis C. To that end, example system 700 includes a split acceleration tube 705 (e.g., split acceleration tube 130 of FIG. 1, 315 of FIGS. 3-4C, and 510 of FIG. 5), an objective lens assembly 710 defining an aperture 715, a separator, a projection system 725 disposed on the second axis B, one or more electron optics 730 disposed on the second axis B between the projection system 725 and an image plane 735. In FIGS. 7A-7B, one or more beams (e.g., multiple beamlets) of charged particles are substantially aligned with the third axis C and directed toward the separator 720. To that end, example system 700 can include a charged particle source and one or more condenser optics.

The example system of FIG. 7A and FIG. 7B describe embodiments of the present disclosure for which the incident beam(s) of primary charged particles (e.g., primary electrons, primary ions, etc.) are made to follow a curved trajectory, initially at a trajectory that is substantially aligned with the third axis C and redirected to be substantially aligned with the first axis A. In this way, the one or more charged-particle optical elements of the primary column (e.g., primary column 105 of FIG. 1, example system 200 of FIG. 2) can include multiple electromagnetic optics configured to redirect secondary electrons from a substantial alignment with a first direction (e.g., X) to a second direction substantially aligned with second axis B (e.g., via the action of the separator 720) and to redirect primary electrons from a third direction (e.g., substantially aligned with the first axis C) to the first direction, the third direction being oriented at an angle, B, relative to the first direction. Advantageously, the example system 700 can improve the range of operating conditions over which the charged particle beam systems of the present disclosure can operate. For example, additional and/or alternative charged particle optical elements can be included to decouple the energy of the primary charged particle beam(s) from the operating parameters of the separator 720, thereby permitting the separator a wider operating window that can improve the sensitivity and robustness of the overall example system 700.

Example system 700 is shown with a “virtual” acceleration tube, whereby some components are coupled with bias circuitry configured to apply a bias voltage to the components and other components are coupled to ground and disposed at a distance from the beam(s) to reduce the risk of interference with the charged particles. Advantageously, a virtual acceleration tube can simplify the internal structures used in the primary and secondary columns. For example, the projection system 725 can include magnetic lenses that can be disposed “external” to the acceleration tube. In some cases, however, the projection system 725 can include one or more electron optical elements disposed in the acceleration tube and coupled with electrical bias circuitry configured to apply a potential to the electron optical elements. For example, the example system 700 can include a stigmator assembly 747. The stigmator assembly 747 can be disposed on the third axis C and can be configured to realign the primary charged particle beam(s) to enter the separator 720 at an appropriate entrance trajectory to leave the separator 720 in substantial alignment with the first axis A. Similarly, the optics 730 can include a stigmator assembly, disposed on the second axis B and configured to realign the beam(s) of charged particles with a detector positioned at the image plane 735.

In some embodiments, a physical material is used for at least a portion of the acceleration tube. For example, FIG. 7A includes a physical portion of the common segment (e.g., common segment 335 of FIG. 3) disposed at least partially in the aperture 715 of the objective lens assembly 710. In this example, the magnetic fields applied by the objective lens elements, as described in more detail in reference to FIG. 3, can be transmitted through the material of the acceleration tube (e.g., a dielectric or otherwise nonconducting material).

FIG. 7B illustrates an example system 700 including opposing curved trajectories. In the example of FIG. 7B, the separator 720 can be configured such that a first Lorentz bending force is applied to primary charged particles introduced along the third axis C and entering the separator 720 at a first side 755, and a second Lorentz bending force is applied to secondary charged particles introduced along the first axis A and entering the separator 720 at a second side 760. For example system 750, with the second axis B and the third axis C being symmetrically opposed across the first axis A, the separator 720 can be configured to apply an opposing bending force (e.g., having an opposite sign) to the primary charged particles, relative to the secondary charged particles. The bending force can be substantially equal or different, based at least in part on the operating parameters of the other components of the example system 750. In this way, the separator 720 can be configured to concurrently apply a first force to primary charged particles at a first energy and a second force to secondary charged particles at a second energy, in one or more beams, as described in more detail in reference to FIGS. 4A-4C.

In the preceding description, various embodiments have been described. For purposes of explanation, specific configurations and details have been set forth in order to provide a thorough understanding of the embodiments. However, it will also be apparent to one skilled in the art that the embodiments may be practiced without the specific details. Furthermore, well-known features may have been omitted or simplified in order not to obscure the embodiment being described. While example embodiments described herein center on charged particle beam systems, and multibeam SEM systems in particular, these are meant as non-limiting, illustrative embodiments. Embodiments of the present disclosure are not limited to such embodiments, but rather are intended to address analytical instruments systems for which a wide array of material samples can be analyzed to determine chemical, biological, physical, structural, or other properties, among other aspects, including but not limited to chemical structure, crystal structure, physical structure, electronic properties, electrical performance, trace element composition, or the like.

Some embodiments of the present disclosure include a system including one or more data processors and/or logic circuits. In some embodiments, the system includes a non-transitory computer readable storage medium containing instructions which, when executed on the one or more data processors and/or logic circuits, cause the one or more data processors and/or logic circuits to perform part or all of one or more methods and/or part or all of one or more processes and workflows disclosed herein. Some embodiments of the present disclosure include a computer-program product tangibly embodied in non-transitory machine-readable storage media, including instructions configured to cause one or more data processors and/or logic circuits to perform part or all of one or more methods and/or part or all of one or more processes disclosed herein.

The terms and expressions which have been employed are used as terms of description and not of limitation, and there is no intention in the use of such terms and expressions of excluding any equivalents of the features shown and described or portions thereof, but it is recognized that various modifications are possible within the scope of the claims. Thus, it should be understood that although the present disclosure includes specific embodiments and optional features, modification and variation of the concepts herein disclosed may be resorted to by those skilled in the art, and that such modifications and variations are considered to be within the scope of the appended claims.

Where terms are used without explicit definition, it is understood that the ordinary meaning of the word is intended, unless a term carries a special and/or specific meaning in the field of charged particle microscopy systems or other relevant fields. The terms “about” or “substantially” are used to indicate a deviation from the stated property within which the deviation has little to no influence of the corresponding function, property, or attribute of the structure being described. In an illustrated example, where a dimensional parameter is described as “substantially equal” to another dimensional parameter, the term “substantially” is intended to reflect that the two parameters being compared can be unequal within a tolerable limit, such as a fabrication tolerance or a confidence interval inherent to the operation of the system. Similarly, where a geometric parameter, such as an alignment or angular orientation, is described as “about” normal, “substantially” normal, or “substantially” parallel, the terms “about” or “substantially” are intended to reflect that the alignment or angular orientation can be different from the exact stated condition (e.g., not exactly normal) within a tolerable limit. For numerical values, such as diameters, lengths, widths, or the like, the term “about” can be understood to describe a deviation from the stated value of up to +10%. For example, a dimension of “about 10 mm” can describe a dimension from 9 mm to 11 mm.

The description provides exemplary embodiments, and is not intended to limit the scope, applicability or configuration of the disclosure. Rather, the ensuing description of the exemplary embodiments will provide those skilled in the art with an enabling description for implementing various embodiments. It is understood that various changes may be made in the function and arrangement of elements without departing from the spirit and scope as set forth in the appended claims. Specific details are given in the description to provide a thorough understanding of the embodiments. However, it will be understood that the embodiments may be practiced without these specific details. For example, specific system components, systems, processes, and other elements of the present disclosure may be shown in schematic diagram form or omitted from illustrations in order not to obscure the embodiments in unnecessary detail. In other instances, well-known circuits, processes, components, structures, and/or techniques may be shown without unnecessary detail.

What is claimed is:

1. A charged particle beam system, comprising:
an objective lens assembly, defining an aperture collocated with a first axis;
an acceleration tube, defining a bifurcation, including:
a primary segment, substantially concentric with the first axis;
a secondary segment, intersecting the primary segment at the bifurcation, the secondary segment being oriented and substantially concentric with a second axis at an angle, α, relative to the first axis; and
a common segment, disposed at least partially in the aperture; and
a separator, including one or more charged-particle optical elements disposed in the common segment and configured to apply a deflection force to electrons having a negative velocity in a first direction, wherein the deflection force redirects the electrons toward a second direction substantially aligned with the second axis.

2. The charged particle beam system of claim 1, wherein the acceleration tube is configured to increase a magnitude of the negative velocity of the electrons in the first direction.

3. The charged particle beam system of claim 1, wherein the one or more charged-particle optical elements comprises a Wien filter, coupled with control circuitry configuring the Wien filter to apply negligible or substantially no deflection force to primary electrons having a positive velocity in the first direction.

4. The charged particle beam system of claim 1, wherein the separator is coupled with bias circuitry configured to apply a bias potential to the separator.

5. The charged particle beam system of claim 1, further comprising a projection system, disposed along the second axis.

6. The charged particle beam system of claim 5, wherein the projection system comprises one or more electromagnetic elements disposed in the acceleration tube and coupled with bias circuitry configured to apply a potential to the electromagnetic elements.

7. The charged particle beam system of claim 5, wherein the projection system comprises one or more electromagnetic elements disposed external to the acceleration tube.

8. The charged particle beam system of claim 5, wherein the projection system comprises a stigmator assembly.

9. The charged particle beam system of claim 1, wherein the electrons are secondary electrons.

10. The charged particle beam system of claim 1, further comprising an aperture array element, disposed on the first beam axis and configured to generate multiple beamlets of primary electrons having a nonzero velocity along the first beam axis in the first direction.

11. The charged particle beam system of claim 1, wherein the angle, α, is a first angle, and wherein the one or more charged-particle optical elements comprises a magnetic prism configured to redirect the electrons from the first direction to the second direction and to redirect primary electrons from a third direction to the first direction, the third direction being oriented at a second angle, B, relative to the first direction.

12. The charged particle beam system of claim 1, wherein the objective lens assembly comprises a multiple-gap objective lens.

13. The charged particle beam system of claim 1, wherein the objective lens assembly comprises a magnetic lens and an immersion lens or the magnetic lens and an electrostatic lens.

14. The charged particle beam system of claim 1, wherein the angle, α, is from about 5 degrees to about 40 degrees.

15. An acceleration tube, comprising:
a primary segment, substantially concentric with a first axis;
a secondary segment, contiguous with the primary segment at a bifurcation of the acceleration tube, the secondary segment being oriented and substantially concentric with a second axis at an angle, α, relative to the first axis; and
a common segment; and
a separator, including one or more charged-particle optical elements disposed in the common segment and configured to apply a deflection force to charged particles having a negative velocity in a first direction, wherein the deflection force redirects the electrons toward a second direction substantially aligned with the second axis.

16. The acceleration tube of claim 15, wherein the acceleration tube is configured to increase a magnitude of the negative velocity of the charged particles in the first direction.

17. The acceleration tube of claim 15, wherein the one or more charged-particle optical elements comprises a Wien filter, coupled with control circuitry configuring the Wien filter to apply negligible or substantially no deflection force to primary charged particles having a positive velocity in the first direction.

18. The acceleration tube of claim 15, wherein the acceleration tube further comprises a dielectric material serving as a physical tube, within which optical components are biased to a tube potential and external to which the optical components are coupled with ground or biased to a potential other than the tube potential.

19. The acceleration tube of claim 15, wherein the acceleration tube further comprises an accelerator assembly, disposed in the common segment and including a plurality of annular electrodes, the accelerator assembly being coupled with bias circuitry configured to apply a bias voltage to the annular electrodes.

20. The acceleration tube of claim 19, wherein the acceleration tube further comprises a substrate, disposed in the common segment and coupled with the accelerator assembly, the substrate defining multiple apertures configured to selectively transmit a portion of the charged particles incident on the substrate.
